(19) United States
(12) Patent Application Publication
(10) Pub. No.: US 2010/0127324 A1
(43) Pub. Date: May 27, 2010

(54) Trench MOSFET with terrace gate and self-aligned source trench contact

(75) Inventor: Fu-Yuan Hsieh, Kaohsiung (TW)

Correspondence Address: BACON & THOMAS, PLLC, 625 SLATERS LANE, FOURTH FLOOR, ALEXANDRIA, VA, 22314-1176, US

(73) Assignee: FORCE MOS TECHNOLOGY CO., LTD., Kaohsiung (TW)

(21) Appl. No.: 12/292,781

(22) Filed: Nov. 26, 2008

(51) Int. Cl. H01L 27/088; H01L 21/8234

(52) U.S. Cl. 257/334; 438/270; 257/E27.06; 257/E21.616

(57) ABSTRACT

A trench MOSFET with terrace gate is disclosed for self-aligned contact. When refilling the gate trenches, the deposited polysilicon layer is higher than the sidewalls of the trenches to be used as a terrace gate of the MOSFET. The source contact width is determined by mesa width between two adjacent trenches minus 2 times of the oxide thickness deposited on the mesa instead of contact mask width which is wider than silicon contact width. Therefore, the position of source contact is still unchanged even if the misalignment of trench mask happens. At the same time, by using terrace gates, the Rg is thus reduced because the terrace gate provides more polysilicon as gate material than the conventional trench gate.

### BACKGROUND OF THE INVENTION

1. Field of the Invention

This invention relates generally to the cell configuration and fabrication process of trench MOSFET devices. More particularly, this invention relates to a novel and improved cell structure and improved process of fabricating a trench MOSFET with terrace gate for self-aligned source contact.

2. The Prior Arts

Please refer to FIG. 1 for a conventional structure of MOSFET. The trench MOSFET is formed on an N+ substrate 900 on which an N doped epitaxial layer 902 is grown. Inside said epitaxial layer 902, a plurality of trenches 910a are etched and filled with N+ doped poly within trenches to serve as trench gates 910 over an insulating layer 908. Between each trench, there is a P-body region 912 introduced by Ion Implantation, and n+ source regions 914 near the top surface of said P-body area. Said source regions are connected to source metal 920 via source contact trench 916 through a layer of insulator 918. Said source contact trenches 916 are filled with Ti/TiN/W or Co/TiN/W or Mo/TiN/W to serve as contact metal, at the same time, underneath each source contact trench 916, an area of heavily P+ doped is formed to reduce the resistance between source and body region. As illustrated in FIG. 1, Iav is the avalanche current originated from the trench bottom when avalanche occurs, which will trigger a parasitic n+/P/N turning on if Iav*R>0.7V where R is parasitic resistance underneath n+ source and between channel and p+ region as shown in FIG. 1. Therefore, the avalanche current Iav is strongly dependent on the resistance R (the lower is the R, the higher is the Iav).

There are two technological constraints encountered by conventional trench MOSFET structure introduced above: High gate resistance Rg due to less polysilicon refilled within the gate trench when trench depth and width become shallower and narrower; and non-uniform distribution of avalanche current Iav and on-resistance Rds across wafer due to non-self-aligned source contact to trench. Both the constrains are explained as below:

To further reduce the Qgd and Rds, trench width of conventional structure is often narrow/shallow, which also meets the requirement of higher cell density. However, a high Rg will therefore be introduced when refilling polysilicon material within this narrow/shallow gate trench.

Another constraint of the structure in FIG. 1 is that, there is no self-aligned source contact to trench, resulting in and a misalignment between contact and trench which will cause non-uniform distribution of UIS (Unclamp inductance Switching) current or avalanche current Iav across wafer, as well as on-resistance Rds between drain and source. And the parasitic N+PN bipolar will turn on when Iav*R>0.7V (see FIG. 1).

Referring to FIG. 1 again, the resistance R between channel and P+ area 919 underneath n+ source 914 bottom is proportional to space Sct between contact 916 and gate 910. Therefore, the space Sct plays very important role in device ruggedness. If the Sct is too wide, the avalanche current Iav is significantly degraded (FIG. 3) while it is too narrow, Rds is drastically increased (FIG. 4) due to the P+ area 919 touching to channel region (FIG. 2), causing high threshold voltage. Those are meaning that the misalignment between contact and trench will result in low avalanche current or UIS on one side and high Rds on another side inside a P-body region, as shown in FIG. 2.

Prior arts US 2006/0071268 and U.S. Pat. No. 7,285,822 have disclosed terrace gate structures with a gate disposed in the trench having a gate top surface that extends above top body surface. However, the terrace gate structures in prior arts do not have self-aligned source contact structure into silicon with equal space between contact trench and gate trench as shown in FIG. 6 when misalignment occurs between contact and trench masks.

Accordingly, it would be desirable to provide a trench MOSFET element with reduced Rg and self-aligned source contact to avoid those problems mentioned above.

### SUMMARY OF THE INVENTION

It is therefore an object of the present invention to provide new and improved trench MOSFET element and manufacture process to reduce the gate resistance Rg and solve the problems may caused by the misalignment between contact and trench.

One aspect of the present invention is that, the conventional poly gate within gate trench is replaced by a terrace gate, which will provide additional poly over silicon mesa area to further reduce gate resistance Rg.

Another aspect of the present invention is that, a self-aligned source contact is employed to solve the UIS current or avalanche current Iav and Rds non-uniform distribution issue resulted from misalignment between contact and trench as introduced above.

Another aspect of the present invention is that, in a preferred embodiment, the Ti/TiN/Al alloys is refilled into the contact trenches to serve as contact metal as well as source,metal, by using this method, the fabricating cost is thus reduced.

Briefly, in a preferred embodiment, the present invention disclosed a trench MOSFET element formed on an N+ substrate coated with back metal Ti/Ni/Ag on rear side as drain. Onto said substrate, grown an N epitaxial layer and a plurality of trenches were etched wherein, especially, trench for gate connection is wider than trenches. To fill these trenches, doped poly was deposited not within those trenches but to form terrace gates above an insulating layer. P-body regions are extending between said trenches with a layer of source region near the top surface of said P-body region between trenches. Above the whole structure, a layer of oxide was deposited to form self-aligned contact structure with silicon contact width which is not determined by contact mask but mesa width and the oxide thickness. When etching into silicon portion, the two sides of the space between each source contact plug to adjacent trench are always equals to each other no matter any misalignment because source contact width into silicon is only determined by the oxide thickness and mesa width between two adjacent terrace gates instead of the contact mask which will causes misalignment between contact to trench gate, therefore, the self-aligned is achieved. Additional, a heavily P doped area was implanted around the bottom of contact trenches to reduce the resistance between source and body region. Metal plugs of Ti/TiN/W, or Co/TiN/W or Mo/TiN/W are used to refill the trench contacts and connected to source metal layer of Al Alloys or Cu and gate metal layer of the same material through a thin layer of Ti or Ti/TiN.

To further understand the self-aligned source contact, though contact mask is misaligned, contact in silicon is still self-aligned to trench because that contact was etched on bottom of the U-shape oxide profile between two adjacent terrace gates and the two sides of the each source contact plug are always equals to each other even the misalignment occurs.

Briefly, in another preferred embodiment, the trench MOSFET disclosed has the same structure with that of the first embodiment expect that, the material refilled into contact trenches is Ti/TiN/Al alloys and used as source metal layer and gate metal layer respectively as well. By employing this method, no additional front metal layer is needed for source and gate metal interconnection, and therefore reducing the fabricating cost.

These and other objects and advantages of the present invention will no doubt become obvious to those of ordinary skill in the art after having read the following detailed description of the preferred embodiment, which is illustrated in the various drawing Figures.

### BRIEF DESCRIPTION OF THE DRAWINGS

The present invention can be more fully understood by reading the following detailed description of the preferred embodiments, with reference made to the accompanying drawings, wherein:

FIG. 1 is a side cross-sectional view of a trench MOSFET of prior art;

FIG. 2 is a side cross-sectional view of a trench MOSFET of prior art when misalignment happens, causing low UIS and high Rds;

FIG. 3 is a profile showing the dependence of normalized UIS on the space between trench and contact edges;

FIG. 4 is a profile showing the dependence of normalized Rds on the space between trench and contact edges;

FIG. 5 is a cross-section of a trench MOSFET of an embodiment for the present invention with barrier layers/W plug as trench contact metal plugs;

FIG. 6 is a cross-section showing the trench MOSFET of the present invention is self-aligned in source contact when misalignment happens without having low UIS and high Rds issues;

FIG. 7 is a cross-section of a trench MOSFET of another embodiment for the present invention with Ti/TiN/Al alloys as trench contact metal plugs and front metal;

FIGS. 8A to 8J are a serial of side cross sectional views for showing the processing steps for fabricating a trench MOSFET of the present invention; and

FIGS. 9A to 9B are a serial of side cross sectional views for showing the processing steps for fabricating a trench MOSFET of another embodiment of the present invention.

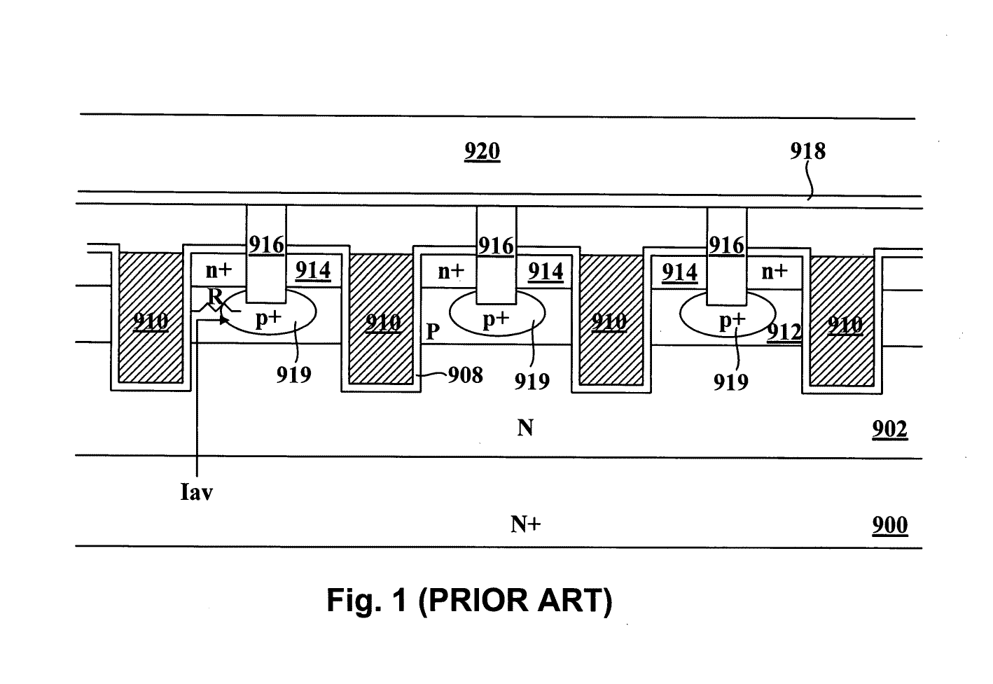

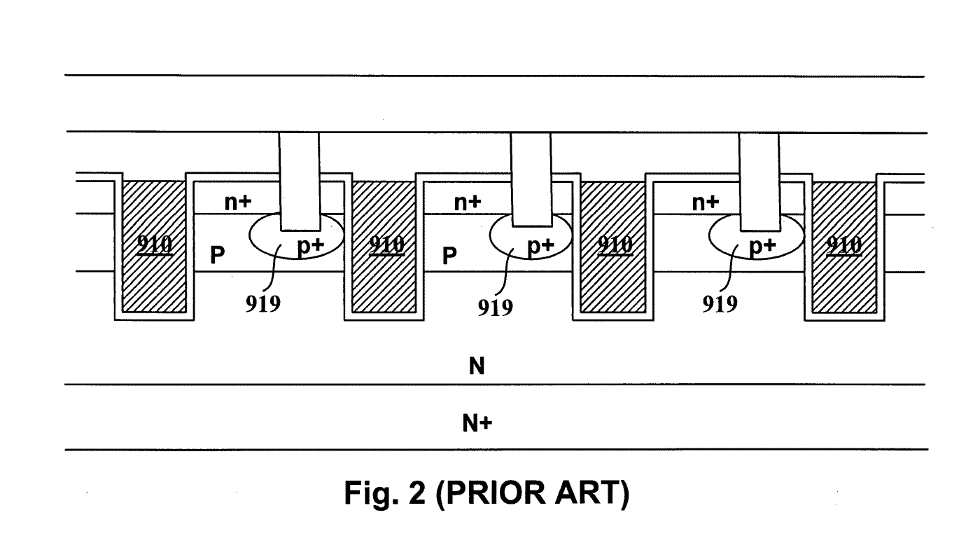

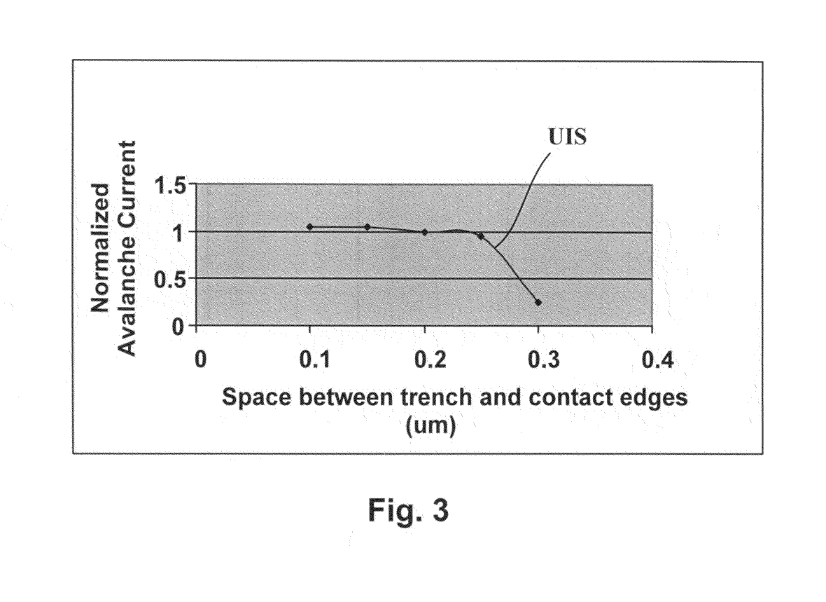

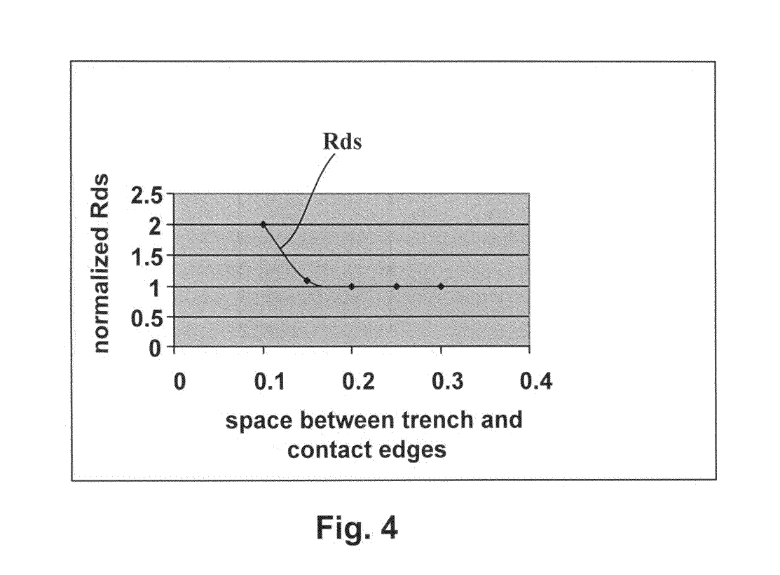

### DETAILED DESCRIPTION OF THE EMBODIMENTS

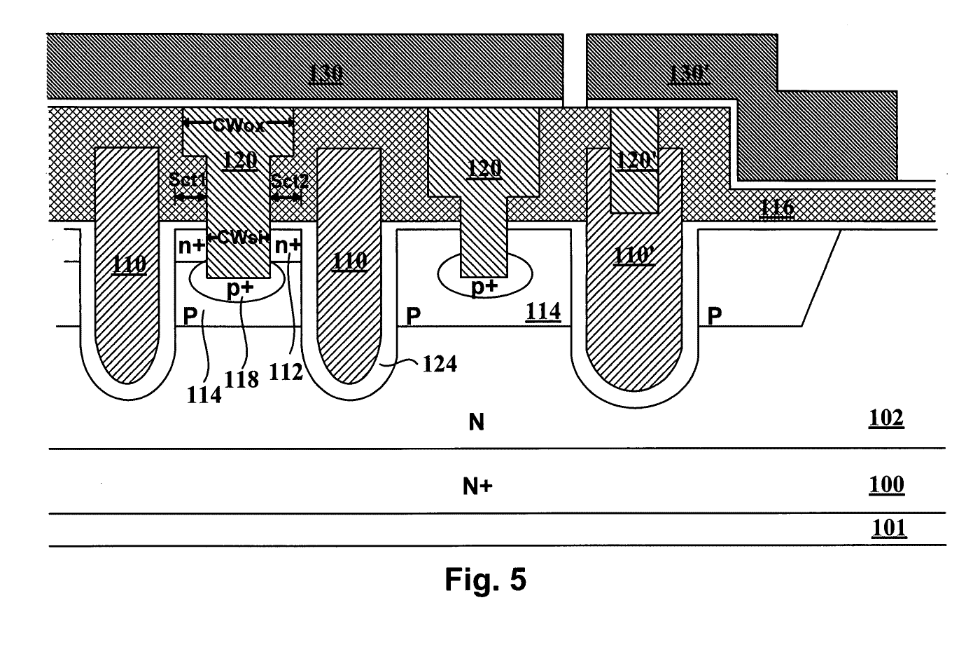

Briefly, in a preferred embodiment, as shown in FIG. 5, the present invention disclosed a trench MOSFET element formed on a substrate 100. Onto the said substrate 100, grown a first semiconductor type epitaxial layer 102 formed by a first semiconductor type silicon layer. The MOSFET element further includes a plurality of trenches filled up polysilicon to form a plurality of narrow trench gates 110 and at least a wide trench gate 110′ which is wider than the trenches 110 for gate connection. Each trench is covered with a gate insulation layer 124 on the inner surface thereof, and to fill these trenches, doped poly was deposited not within those trenches but to form terrace gates, the narrow trench gates 110 and at least a wide trench gate 110′, above the gate insulation layer 124. On the first semiconductor type epitaxial layer 102, a plurality of body regions 114 are formed by a second semiconductor type silicon layer, which are extending between the said trench gates, the narrow trench gates 110 and the wide trench gate 110′, and with a layer of source region 112 near the top surface of an according body region 114 between the narrow trench gates 110 and the wide trench gate 110′. The first semiconductor type silicon layer is selected from one of N-type semiconductor and P-type semiconductor while the second semiconductor type silicon layer is selected from the other. Above the whole structure, a terrace oxide layer 116 is deposited to form a self-aligned contact structure, and a source metal layer 130 and a gate metal layer 130′ are formed on the top of the terrace oxide layer 116. The MOSFET element further includes a plurality of source metal plugs 120 for electrically connecting the source metal layer 130, the source regions 112, and the body regions 114. The MOSFET element further includes at least a gate metal plug 120′ for electrically connecting the gate metal layer 130′ and the wide trench gate 110′. Moreover, the each source metal plug 120 has an upper part with a silicon contact width, CWsi, contacted the source metal layer 130 and an lower part with an oxide contact width, CWox, contacted the gate metal layer 130′. The silicon contact width CWsi is smaller than oxide contact width CWox since the upper part of the source metal layer 130 is protruded with a distance, Sct1, at one side and with a distance, Sct2, at another one side in the cross section view. The Sct1 is always equals to the Sct2 no matter any misalignment because source contact width is determined by the oxide 116 thickness and mesa width between two adjacent terrace gates instead of the oxide contact width CWox, therefore, the self-aligned is achieved.

Additional, the each source metal plugs 120 has a heavily second semiconductor type doped area implanted around the bottom thereof to reduce the resistance between the source region 112 and the body region 114. The each metal plug 120 is made of Ti/TiN/W, Co/TiN/W, or Mo/TiN/W, and so the gate metal plug 120′ is. The source metal layer 130 is made of Al Alloys or Cu, and the gate metal layer 130′ is made of the same material through a thin layer of Ti or Ti/TiN.

A contact implantation part 118 is carried out by a second semiconductor type doping, which will help to form a low-resistance contact between the source metal plugs 120 and the body region 114. The each said contact implantation part 118 is doped underneath the bottom of the corresponding source metal plug 120 with the same doping type as the body region 114 and the doping concentration thereof is heavier than the body region 114 to reduce resistance between the corresponding source region 112 and the corresponding body region 114.

In the said MOS element, the substrate 100 can be coated with a back metal 101 on rear side as drain, and the back metal 101 can be made of Ti/Ni/Ag.

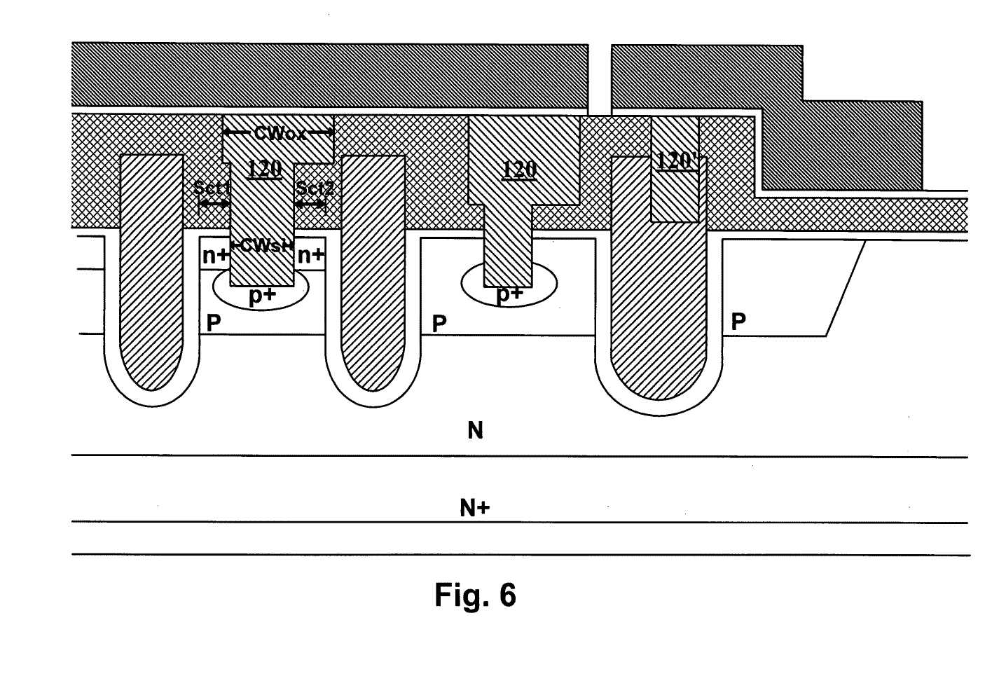

To further understand the self-aligned source contact, the source metal plugs 120, case when misalignment happens is shown in FIG. 6. Though contact mask is misaligned, contact in silicon is still self-aligned to trench because that contact was etched on bottom of the U-shape oxide profile between two adjacent terrace gates and Sct1 always equals to Sct2 even the misalignment occurs.

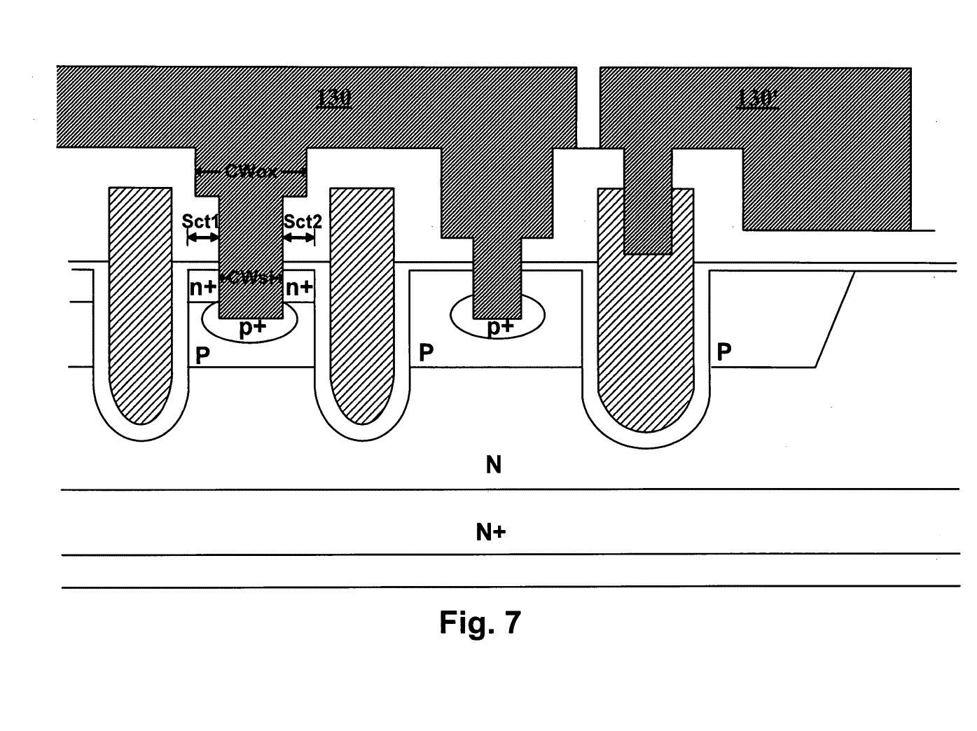

Briefly, in another preferred embodiment, as shown in FIG. 7, the trench MOSFET disclosed has the same structure with that of the first embodiment expect that, the material refilled into contact trenches is Ti/TiN/Al alloys and used as source metal layer 130 and gate metal layer 130′ respectively as well. By employing this method, no additional front metal layer is needed for source and gate metal interconnection, such as the said source metal plugs 120 and the said gate metal plug 120′, and therefore the fabricating cost is reduced.

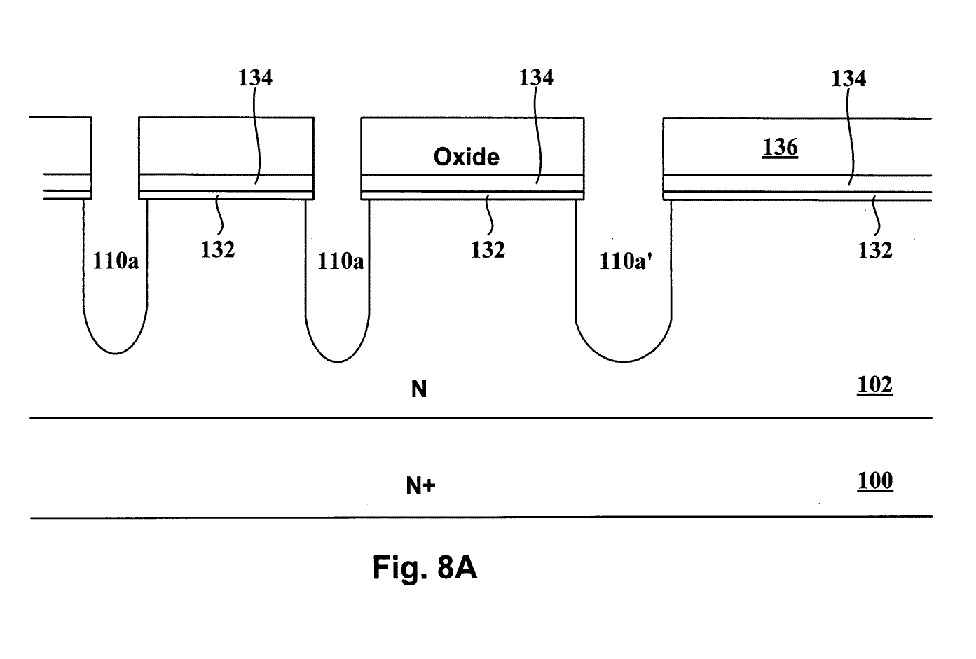

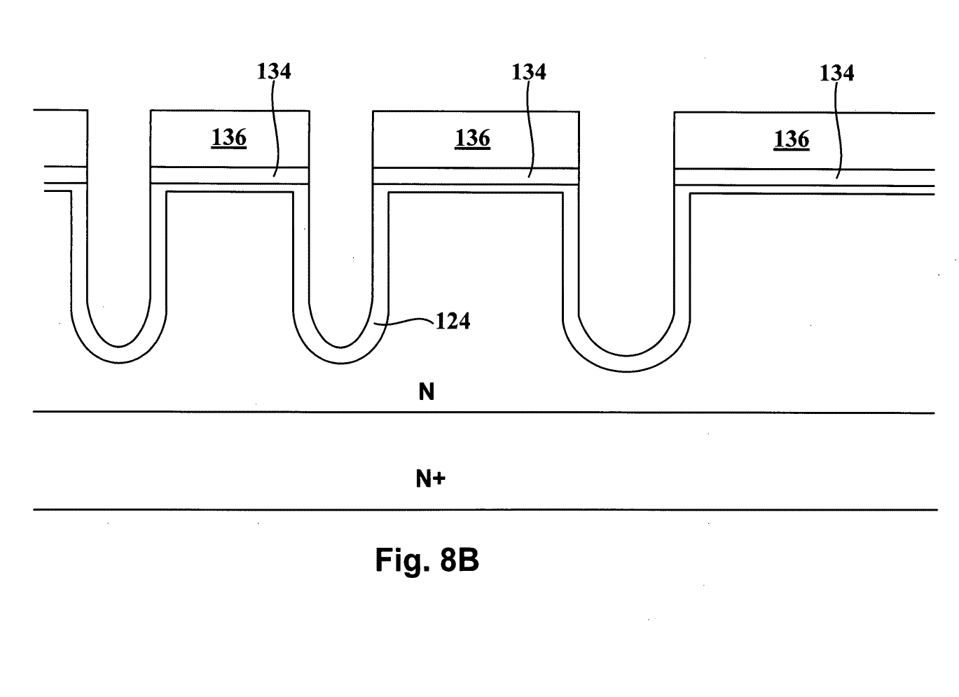

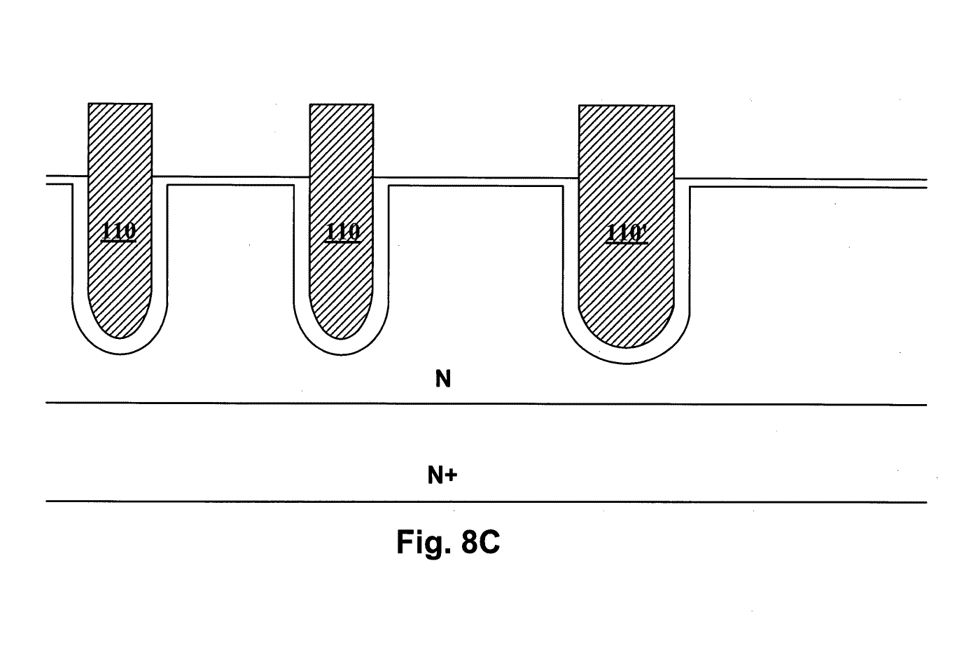

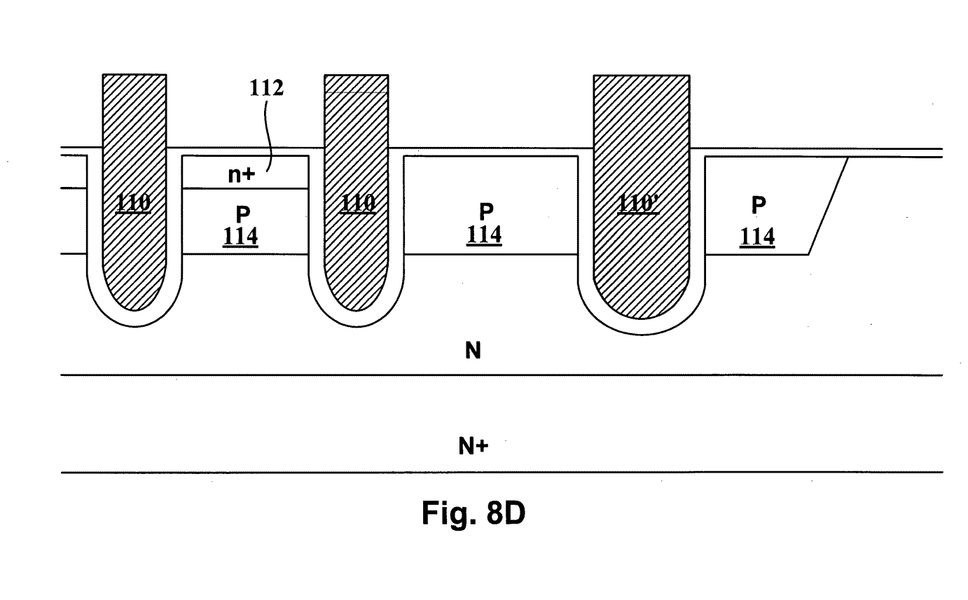

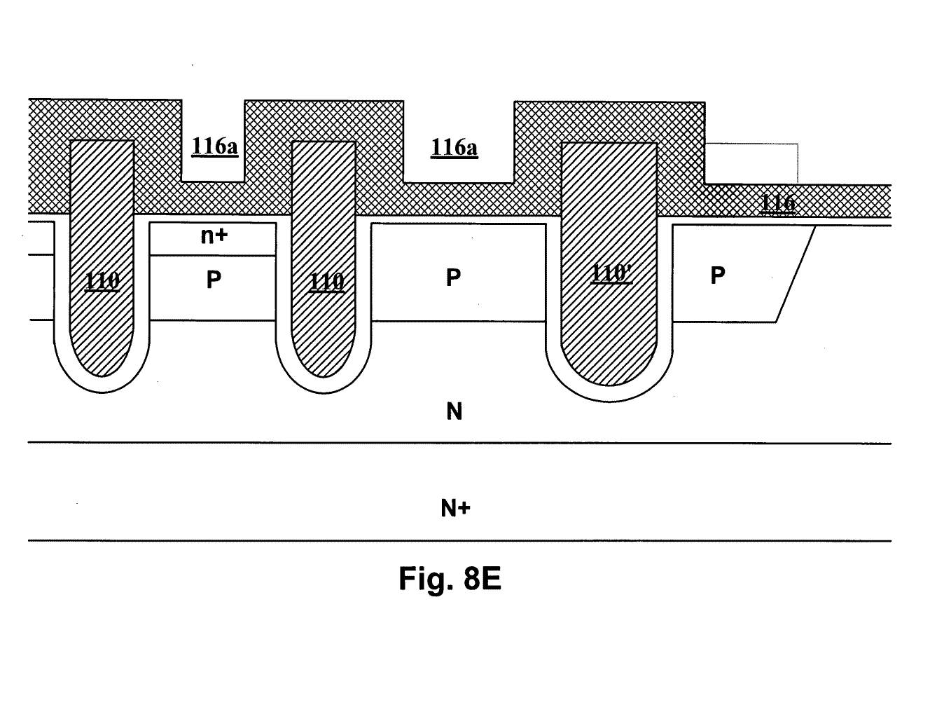

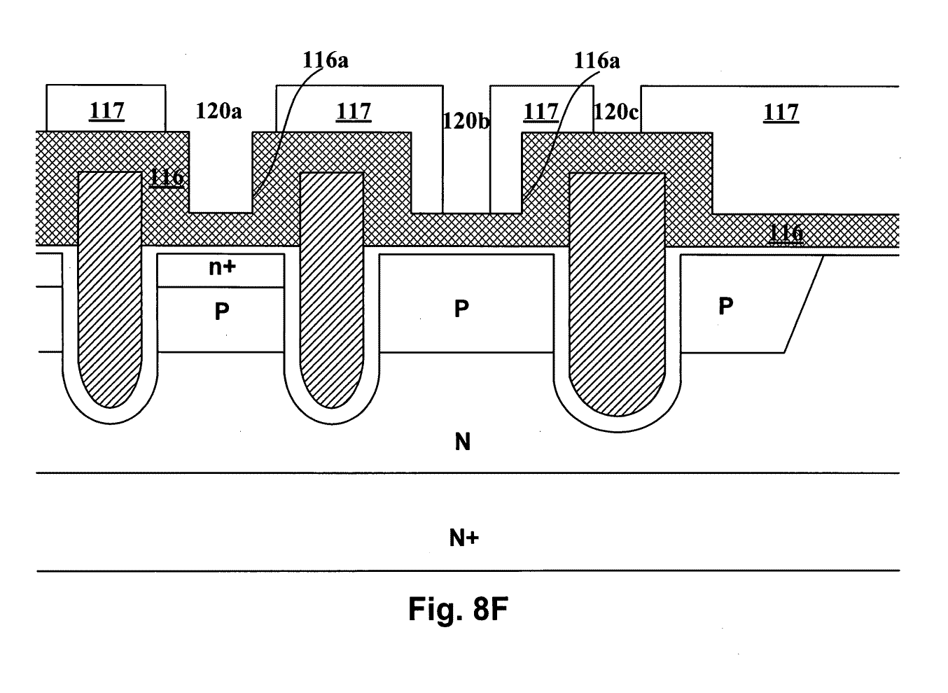

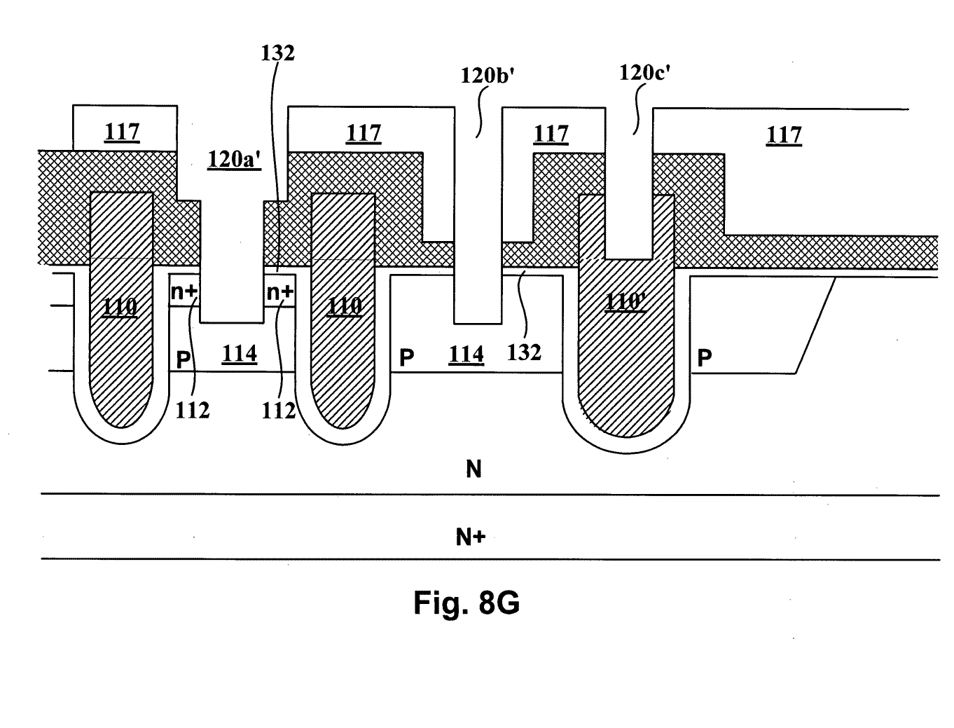

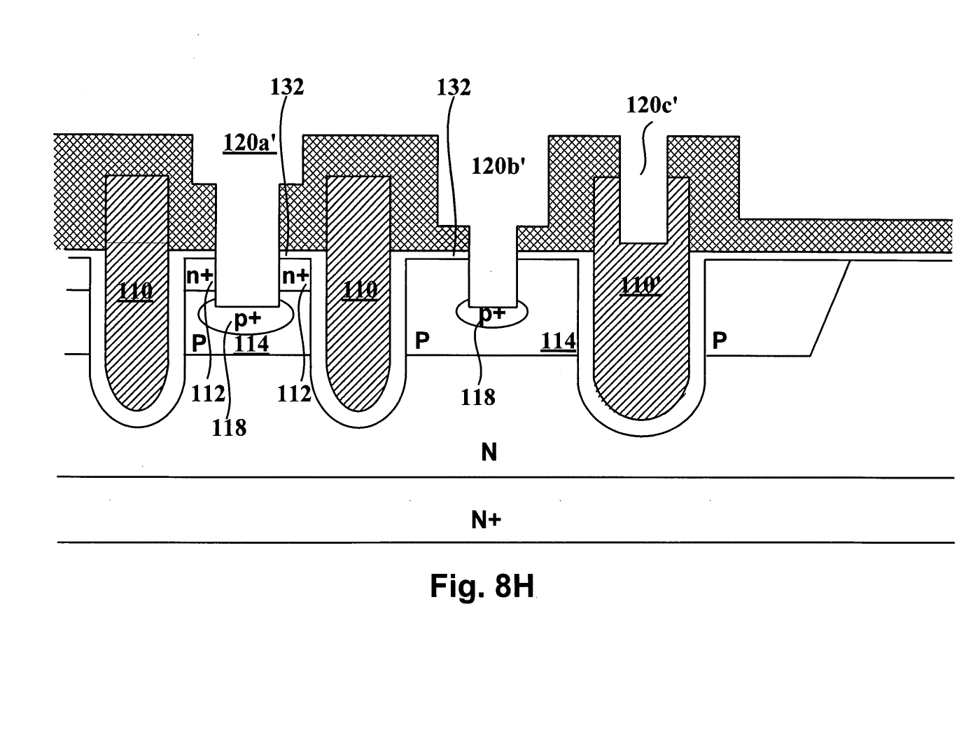

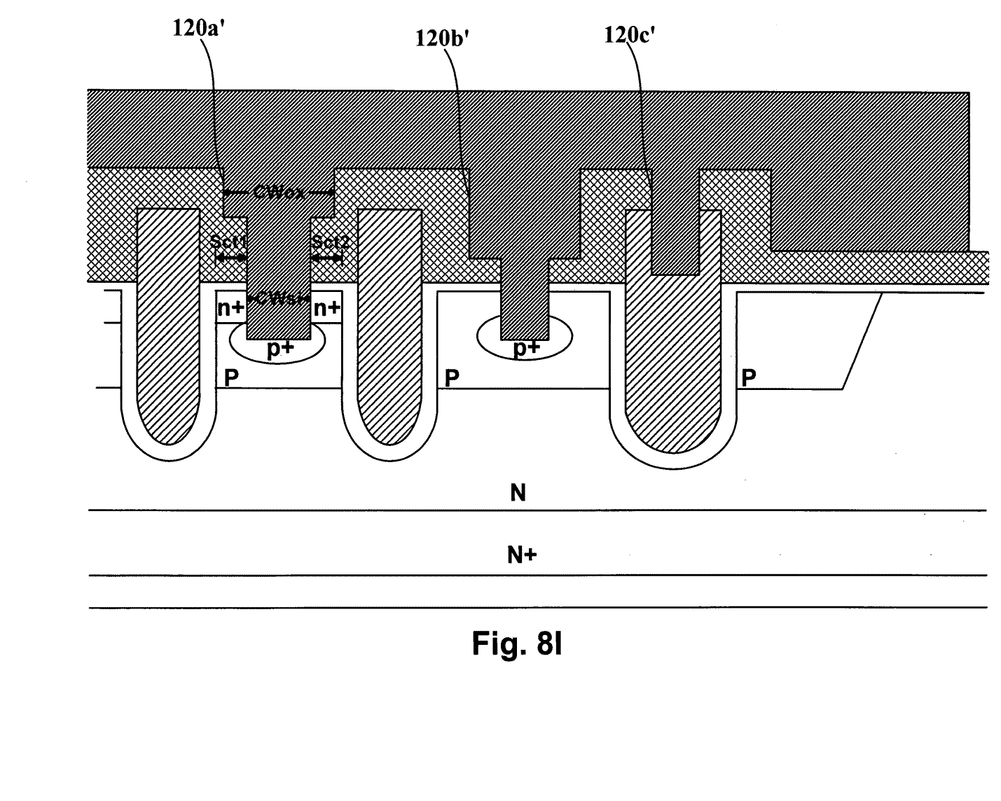

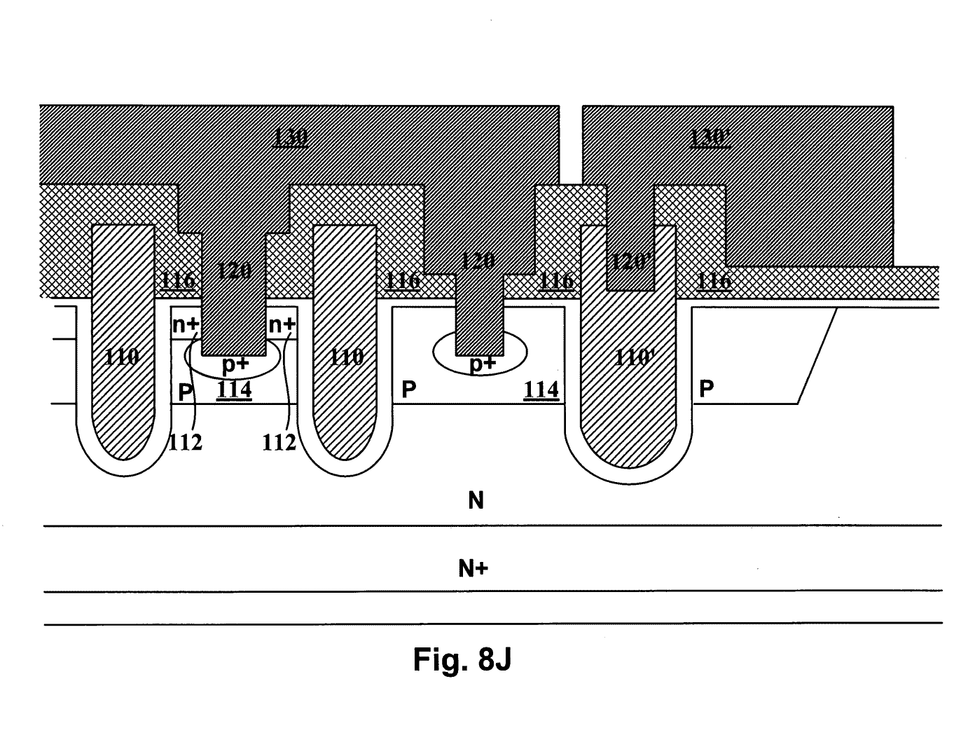

Referring FIGS. 8A to 8I shows a series of exemplary steps that are performed to form the inventive trench MOSFET of the present invention. In FIG. 8A, a first semiconductor type epitaxial layer 102, which can be selected an N-type doped epitaxial layer is formed on a substrate 100, which is first semiconductor type silicon layer with higher first semiconductor type doping concentration and usually is indicate by N+ type. Thereafter, a thin layer of pad oxide 132 is formed with 100˜500 angstrom on the substrate 100. Then, a layer of SiN (silicon nitride) 134 is deposited about 1000˜2000 angstrom covering the whole structure and followed by the deposition of thicker oxide 136 which is about 4000˜8000 angstrom. After those three steps of deposition, a trench mask is applied to define the trenches 110a and 110a′. Through a process of dry oxide/nitride/oxide etching, those trenches are then dry silicon etched and followed with down-stream plasma silicon etch (remove about 100˜300 A silicon) to remove the silicon defect along the trenches caused during the silicon trench etching process and round the trench bottom as well. By the way, the trench 110a′ is wider than trenches 110a and is used for gate connection.

In FIG. 8B, a sacrificial oxide layer is deposited and then removed (not shown) to remove plasma damages may introduced during opening gate trenches, and an oxide layer is grown or deposited along the sidewall of the each trench, and the bottom of the each trench for a gate oxide of the trench MOSFET.

In FIG. 8C, a doped poly is deposited to refill all trenches, and then etched back either by CMP or dry poly etch to form a plurality of terrace gates which are extended upward the top surface of the source regions 112 and the body regions 114. Thereafter, the oxide layer 136 (shown in FIG. 8B) is etched by wet oxide etching, and the removal of SiN layer 134 (shown in FIG. 8B) is followed. Therefore, the terrace gate filled in the trenches 110a is defined as the narrow trench gate 110 while the terrace gate filled in the trench 110a′ is defined as the wide trench gate 110′.

In FIG. 8D, the process continues by second semiconductor type ion implantation and diffusion and by employing a body region mask to define implantation regions to form a plurality of body regions 114. After that, a source mask is applied to define implantation regions for first semiconductor type ion implantation and diffusion to form a plurality of source regions 112. The each source region 112 is formed according to the corresponding body region 114, and the active regions in the trench MOSFET is formed between two adjacent terrace gates, the narrow trench gates 110 and the wide trench gate 110′.

In FIG. 8E, a thick layer of terrace oxide layer 116 is deposited onto the entire surface to form a plurality of concaves 116a which are U-shape oxide structure above the mesa area between two adjacent terrace gates, the narrow trench gates 110 and the wide trench gate 110′. Because the terrace oxide layer 116 is almost uniformly grown along the outer surface of the narrow trench gates 110 and the wide trench gate 110′, the each concave 116a is almost positioned at the middle between two adjacent terrace gates, the narrow trench gates 110 and the wide trench gate 110′. The bottom CD (Critical Dimension) of the U-shape oxide structure defines actual contact CD into silicon or Silicon contact CD. Then, referring to FIG. 8F, a contact mask 117 is applied to define etching areas 120a, 120b, and 120c for a contact etching, wherein the etching areas 120a and 120b are corresponding to the action region and the etching area 120c is corresponding to the wide trench gate 110′. Besides, the etching area 120a can be larger than the concave 116a while the etching area 120b can be smaller than the concave 116a.

Referring to FIGS. 8G, 8H, 8I and 8J, an oxide etching is applied to etch the terrace oxide layer 116 and the pad oxide 132 and a silicon etching is applied to etch the source region 112, the body region 114, and the wide trench gate 110′, from the etching areas 120a, 120b, and 120c shown in FIG. 8F. Moreover, after removing the contact mask 117, a plurality of contact trenches 120a′, 120b′, and 120c′ are formed as FIG. 8H shows. A contact implantation part 118 is carried out by a second semiconductor type doping and formed at the bottom of the contact trenches 120a′ and 120b′. Then, a metal deposition is applied to refill contact trenches 120a′, 120b′, and 120c′, and to cover the upper side surface of the MOSFET as FIG. 8I shows so that a metal layer 130a is formed. Thereafter, a metal etching is applied to pattern the upper part of the metal layer 130a which is covered the upper side surface of the MOSFET and to define the source metal layer 130 and the gate metal layer 130′, which are insulated to each other as FIG. 8J shows. At the same time, the lower part of the metal layer 130a, which is filled in the contact trenches 120a′, 120b′, and 120c′, is formed a plurality of metal plugs, the metal plug corresponding to the contact trenches 120a′ or 120b′ is defined as the source metal plug 120 while the metal plug corresponding to the contact trenches 120c′ is defined as the gate metal plug 120′.

The contact implantation part 118 is formed by a BF2 ion implantation process, and the contact implantation part 118 is carried out by a second semiconductor type doping with higher doping concentration than the body region 114.

The said metal layer 130a can be selected from Ti/TiN/Al alloys.

The most important is that the contact CD on the contact mask 117 is large than the actual contact CD into silicon which is determined by the mesa CD between the two adjacent terrace gates and the oxide thickness (i.e. the actual contact CD into silicon=the Mesa CD−2 times of the oxide thickness) the contact CD in silicon or Silicon contact CD is actually determined by the bottom CD of the U-shape oxide structure instead of contact CD on mask. Therefore, the source contact is self-aligned with trench by dry etching oxide on bottom of the U-shape oxide profile between two adjacent terrace gates followed by dry silicon etch. The contact width in the top oxide CWox is larger than that in silicon CWsi, as mentioned above and shown in FIG. 8I.

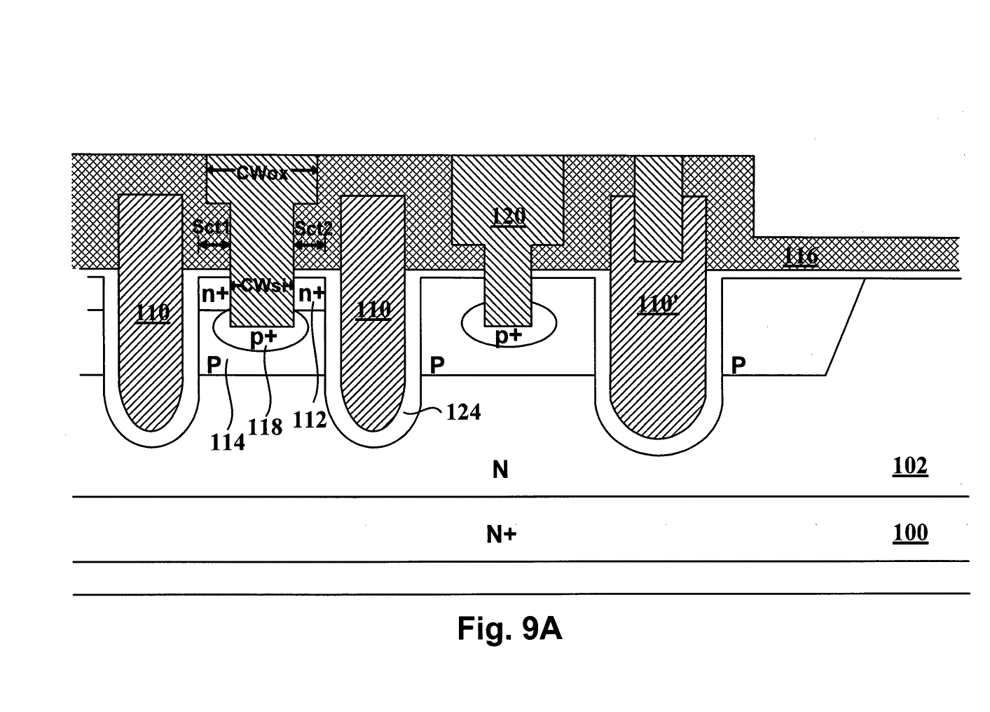

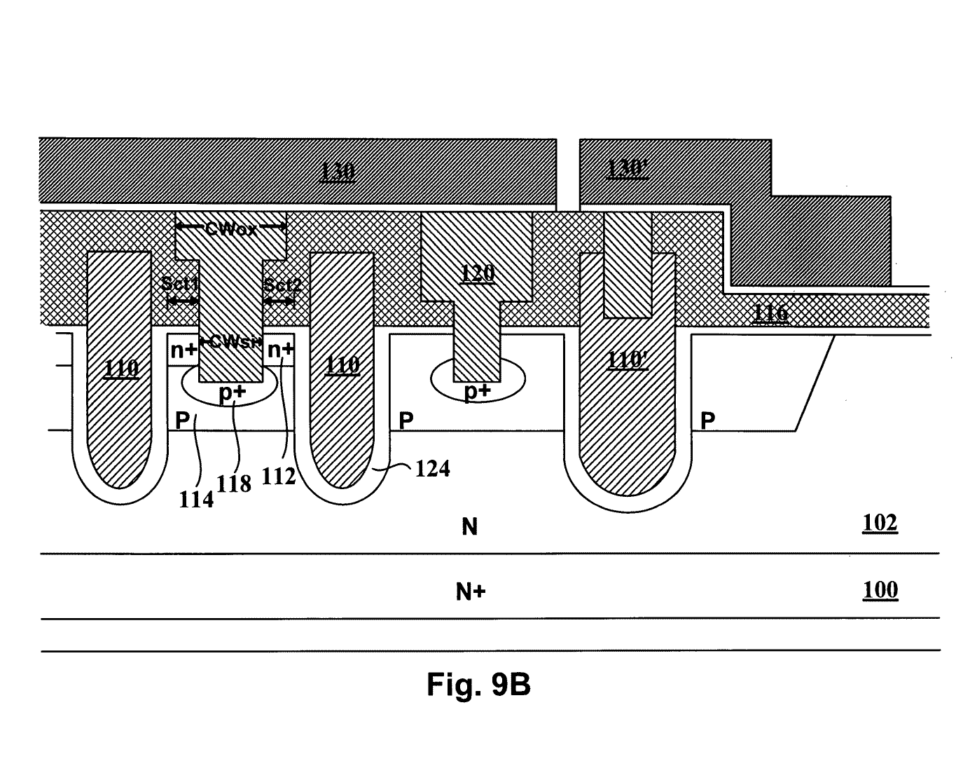

Referring to FIGS. 9A and 9B, in another embodiment, after the metal deposition process, the metal layer 130a is etched back or applied the CMP to remove the upper part of the metal layer 130a covered on the top surface, and then the source metal plugs 120 and the gate metal plug 120′ are formed as FIG. 9A shows. Thereafter, a second metal deposition process is applied and formed the source metal layer 130 and the gate metal layer 130′ on the top surface, which are insulated to each other as FIG. 9B shows.

In this embodiment, the source metal plugs 120 and the gate metal plug 120′ is selected from the Ti/TiN/Al alloys, and so the source metal layer 130 and gate metal layer 130′ can be.

If the first embodiment structure is adopted, after etching contact trenches by dry oxide etch and dry silicon etch, Ti/TiN/W or Co/TiN/W or Mo/TiN/W is deposited to fill in those trenches and then etched back to expose the oxide 116 and contact metal 120 as well, as shown in FIG. 9A. Next, above the whole surface, a thin layer of Ti or Ti/TiN and a thick layer of Al alloys or Cu are deposited in turn. Applying a metal mask, those two layers are etched to be divided into source metal portion and gate metal portion, respectively, as shown in FIG. 9B.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A trench MOSFET, compromising:
a substrate made of first type semiconductor;
an epitaxial layer made of said first type semiconductor over the substrate and having a lower doping concentration than the substrate;
a plurality of body regions made of said second type semiconductor over the epitaxial layer as body regions of the trench MOSFET;
a plurality of source regions made of said first type semiconductor over the body regions as source regions of the trench MOSFET and having a higher doping concentration than the epitaxial layer;
a plurality of narrow trench gates formed to reach the epitaxial layer through the source region and the body region;
at least a wide trench gate formed to reach the epitaxial layer through the body region;
a gate insulation layer formed to wrap the each narrow trench gate and the wide trench gate;
a terrace oxide layer covered on the source regions and the trench gates;
a source metal covered on the insulating layer;
a gate metal covered on the insulating layer isolated to the source;
a plurality of self-aligned source trench contacts are formed with larger contact width on top of said terrace oxide than in silicon contact of which contact width is mainly determined by mesa width between two adjacent trenches minus two times of said terrace oxide thickness deposited on the mesa area instead of contact mask;
a plurality of source contact plugs each of which is extended from the source metal and through the insulating layer to contact the corresponding source regions and the corresponding body region; and
at least a gate contact plug which is extended from the gate metal and through the insulating layer to contact the corresponding wide trench gate;
The source metal is electrically connected to the source regions and the body regions by the source contact plugs; the gate metal is electrically connected to the wide trench gate by the gate contact plug; and the narrow trench gates and the wide trench gate are extended upward the top surface of the source regions and the body regions to form terrace gate structure.

2. The trench MOSFET of claim 1, wherein the each source contact plug is selected form one of Ti/TiN/W, Co/TiN/W, Mo/TiN/W and Ti/TiN Al alloys.

3. The trench MOSFET of claim 1, wherein the gate contact plug is selected form one of Ti/TiN/W, Co/TiN/W, Mo/TiN/W and Ti/TiN/Al alloys.

4. The trench MOSFET of claim 1, wherein the source metal is selected form one of Ti/Al alloys, Ti/TiN/Al alloys, Co/TiN/Al alloys and Mo/TiN/Al alloys.

5. The trench MOSFET of claim 1, wherein the gate metal is selected form one of Ti/Al alloys, Ti/TiN/Al alloys, Co/TiN/Al alloys and Mo/TiN/Al alloys.

6. The trench MOSFET of claim 1, wherein further comprises a plurality of contact implantation parts, and each contact implantation part is doped underneath the bottom of the corresponding source contact plug with the same doping type as the body region and the doping concentration thereof is heavier than the body region.

7. The trench MOSFET of claim 1, wherein further comprises a plurality of doped regions underneath the bottom of the corresponding source metal plug with the same doping type as the body region and the doping concentration thereof is heavier than the body region.

8. The trench MOSFET of claim 1, wherein the spaces between said silicon contact and surrounding trenches are symmetric without affecting by misalignment between trench and contact masks.

9. The trench MOSFET of claim 1, wherein said trench MOSFET has single gate oxide.

10. The trench MOSFET of claim 1, wherein said gate oxide at the bottom of each gate trench is thicker than that on trench sidewall.

11. A method for manufacturing a trenched semiconductor power device comprising the steps of:
Growing epitaxial layer on a heavily doped substrate;
Forming a thin pad layer followed with deposition of a silicon nitride and a thick oxide layer;
Applying a trench mask to open a plurality of gate trenches into the epitaxial layer;
Following with down-stream plasma silicon etch;
Growing and removing a sacrificial oxide;
Forming a gate oxide and depositing a doped polysilicon layer;
Removing the doped polysilicon layer from surface of the epitaxial layer and leave the doped polsilicon in gate trenches;
Removing the thick oxide layer and the silicon nitride layer;
Forming body regions by ion implantation into the epitaxial layer followed by diffusion;
Forming source regions by ion implantation into the body regions;
Depositing a terrace oxide layer to define a contact area to be etched into epitaxial layer;
Applying a contact mask with contact opening larger than the contact area into epitaxial layer which is defined by the second thick oxide layer;
Opening the second thick oxide layer by dry etching followed with dry silicon etch through the source regions and into body regions;
Implanting through said plurality of trenches a contact dopant region with the same type dopant as the body region below the source-body trench contacts.
Depositing and patterning at least one conductive layer to form electrical contacts to sources and gate regions.

12. The trench MOSFET of claim 11, wherein the terrace oxide layer is a thick layer deposited onto the entire surface to form a plurality of concaves between two adjacent terrace gates which comprise the narrow trench gates and the wide trench gate; the each source metal plug and the gate metal plug are formed by a metal deposition which is applied to refill a plurality of contact trenches; and the contact trenches are formed by a plurality of processes comprising:
applying a contact mask which defines a plurality of oxide etching areas corresponding to the action region;
an oxide etching which is applied to etch a plurality of parts of the oxide layer which are under the oxide etching areas; and
a silicon etching which is applied to etch the source region, the body region, and the wide trench gate under where the parts etched during the said oxide etching process.

13. The trench MOSFET of claim 11, wherein further comprises a plurality of contact implantation part, and the each contact implantation part is doped underneath the bottom of the corresponding source metal plug with the same doping type as the body region and the doping concentration thereof is heavier than the body region.
